(19) United States
(12) Patent Application Publication
(10) Pub. No.: US 2007/0190788 A1
(43) Pub. Date: Aug. 16, 2007

(54) WAFER REMOVING FORCE REDUCTION ON CMP TOOL

(76) Inventors: Manoj Balachandran, Wappingers Falls, NY (US); James A. Hagan, Hopewell Junction, NY (US); Ben Kim, Shelburne, VT (US); Deoram Persaud, Bronx, NY (US); Adam D. Ticknor, Poughquag, NY (US); Wei-Tsu Tseng, Hopewell Junction, NY (US)

Correspondence Address: HOFFMAN, WARNICK & D'ALESSANDRO LLC, 75 STATE ST, 14TH FL, ALBANY, NY, 12207, US

(21) Appl. No.: 11/276,137

(22) Filed: Feb. 15, 2006

(51) Int. Cl. H01L 21/302; H01L 21/461; H01L 21/311

(52) U.S. Cl. 438/692; 438/698

(57) ABSTRACT

Reduction of a wafer removing force on a chemical mechanical planarization (CMP) tool that includes planarizing a wafer on a platen at a wafer/platen interface; applying carbonated water to the wafer/platen interface so as to reduce the removing force; and removing the wafer from the platen.

### BACKGROUND OF THE INVENTION

1. Field of the Invention

The present invention relates generally to manufacturing of semiconductor materials and the portion related to chemical mechanical planarization (CMP). More specifically, the present invention provides for reduction of the wafer lift-off force on a CMP tool, and thereby diminishing the chances of wafer breakage.

2. Background Art

In the field of semiconductor manufacturing, one of many steps of manufacturing includes the planarization of the semiconductor wafers. This is typically done via chemical mechanical planarization (CMP) tools. A primary goal of the CMP tooling step is to essentially polish a surface of the wafer so as to render it both planar and smooth.

FIG. 1 depicts a typical CMP tool system 10 wherein a wafer 8 is held face down on a carrier 20 that rotates (about arrow 22), and is pressed against a polishing pad 2 attached on a rotating disk 4, or platen. Various liquids and/or slurries (e.g., colloidal silica) (not shown) are continuously fed to a platen/wafer interface 6 to aid in this polishing. Upon satisfactory completion of the polishing step, the polished wafer 8 is removed from the interface 6, specifically, and from the CMP tool system 10, in general, by applying a lift-off force F₀.

A shortcoming in the current art is that, often, upon lift off of wafer 8 from pad 2 and platen 4 breakage of wafer 8 occurs. Breakage occurs because the mechanical lift-off force (i.e., F₀) necessary can at times exceed the fracture strength of wafer 8. The lift-off force F₀ is high for various reasons, including the flatness and smoothness of both the polished wafer 8 and polishing pad 2. Necessary lift-off force F₀ may be increased further by drag due to rinsing water (not shown) on polishing pad 2. Surface tension at interface 6 and atmospheric pressure further effects necessary lift-off force F₀, as well.

CMP tools that include fixed abrasive polishing pads 2 are particularly prone to wafer 8 breakage because the smooth texture of polishing pads 2 causes very high requisite lift-off forces F₀. Currently, spinning, sweeping, or blowing water off polishing pad 2 just prior to lift-off is used in an attempt to make wafer 8 lift-off more benign and successful. While effective at allowing successful lift-off of wafer 8, these methods increase the likelihood of scratching wafer 8, which is undesirable.

In view of the foregoing, there exists a need for an improvement in CMP technique that reduces wafer removal breakage.

### SUMMARY OF THE INVENTION

In general, methods and a system of reducing wafer removal force on a chemical mechanical planarization (CMP) tool are disclosed.

A first aspect of the present invention provides a method of reducing wafer removing force on a chemical mechanical planarization (CMP) tool, comprising the steps of: planarizing a wafer on a platen at a wafer/platen interface; applying carbonated water to the wafer/platen interface to reduce the removing force; and removing the wafer from the platen.

A second aspect of the present invention provides a system for reducing wafer removing force on a chemical mechanical planarization (CMP) tool, comprising: means for planarizing a wafer on a platen at a wafer/platen interface; means for applying carbonated water to the wafer/platen interface; and means for removing wafer from platen.

A third aspect of the present invention provides a method of reducing wafer removing force on a chemical mechanical planarization (CMP) tool, comprising the steps of: planarizing a wafer on a platen at a wafer/platen interface; applying pressurized carbonated deionized water that is between approximately 40 and 50 degrees Fahrenheit to the wafer/platen interface, to reduce wafer removing force; and removing the wafer from the platen.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts an elevation view of a chemical mechanical planarization (CMP) system in the related art.

FIG. 2 depicts an elevation view of one embodiment of a CMP system, in accordance with the present invention.

FIG. 3 depicts a close up elevation view of a wafer/platen interface of FIG. 2, in accordance with the present invention.

The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION

As indicated above, the present invention provides methods and a system for reducing wafer removing force on a chemical mechanical planarization (CMP) tool.

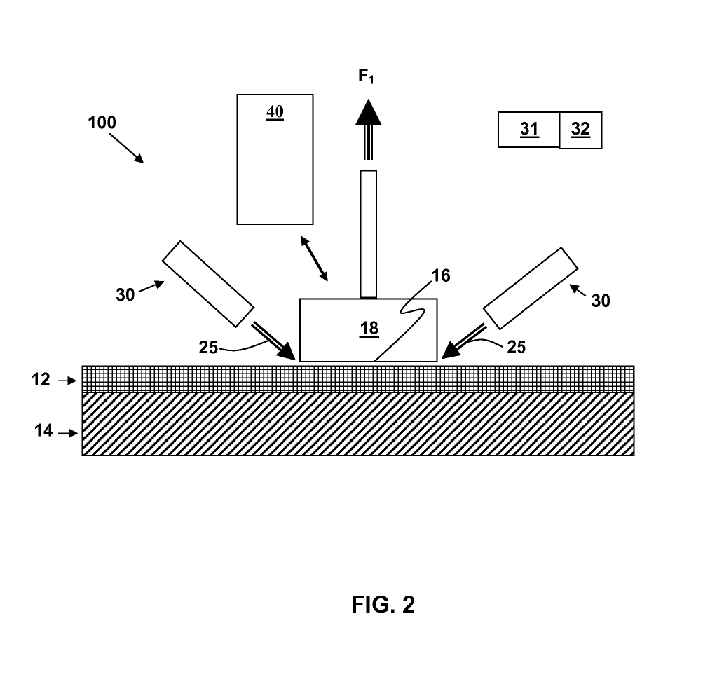

FIG. 2 shows a CMP tool system 100 in accordance with one embodiment of the present invention. A pad 12 resides on a platen 14. Held in a face down configuration, a wafer 18 is rotated against pad 12 so as to polish wafer 18.

Upon completion of polishing wafer 18 but prior to liftoff of wafer 18 from pad 12 and platen 14, carbonated water 25 is applied at interface 16 between wafer 18 and platen 14 (and pad 12). Carbonated water 25 may be applied, for example, via an applicator(s) 30 (e.g., nozzle) in fluid communication with a reservoir 31 and pump 32. Other suitable means now known or later developed may be utilized to provide and apply carbonated water 25 to interface 16.

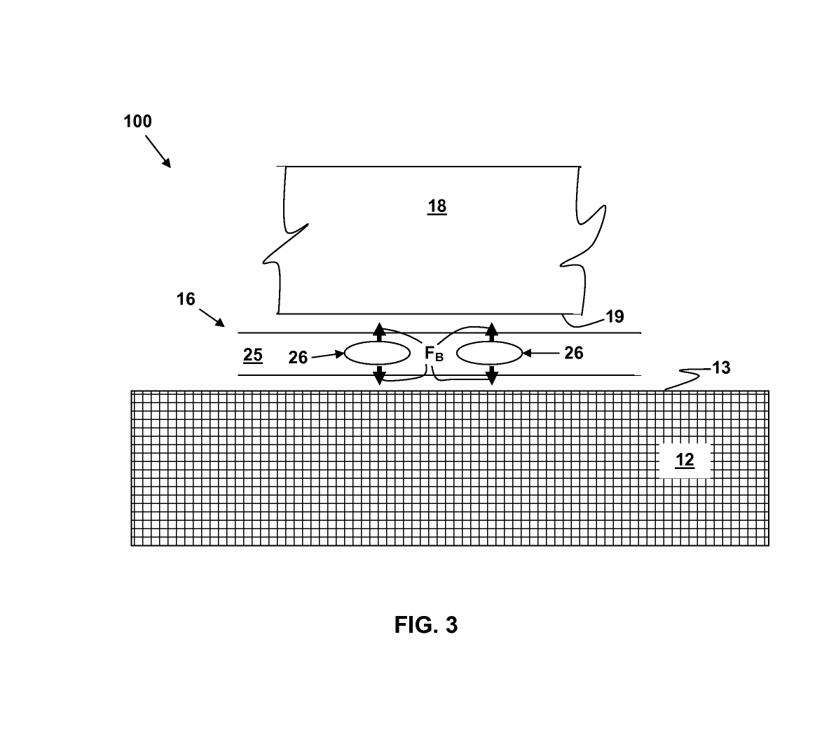

In one embodiment, carbonated water 25 may be deionized carbonated water 25 and may be pressurized so as to be at a higher pressure than the pressure that is ambient. Similarly, carbonated water 25 may be colder than ambient temperature, and may be chilled prior to application, for example, to a temperature in the range of approximately 40-50° Fahrenheit. For example, relative motion of pad 12 and wafer 18, prior to application of carbonated water 25, may cause a warming of a temperature in area of interface 16. As the close-up view in FIG. 3 depicts, carbonated water 25 has been placed at interface 16 between wafer 18 and pad 12 (and platen 14).

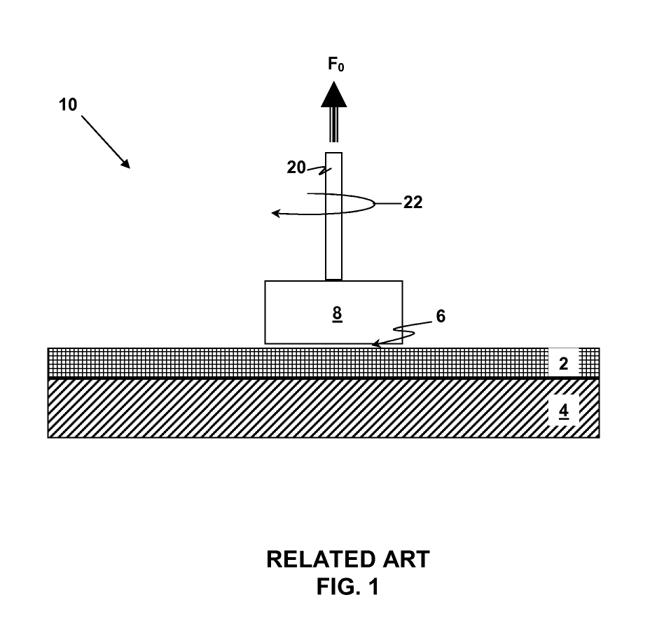

Bubbles 26 of carbon dioxide (CO₂) gas form in interface 16 between wafer 18 and platen 14 from carbonated water 25. As bubbles 26 of carbon dioxide gas form and as the temperature of carbonated water 25 increases, due to ambient temperature being warmer than carbonated water 25, bubbles 26 increase in size. Force F_{B} is exerted against surface 13 of pad 12 and surface 19 of wafer 18, thereby decreasing the necessary lift-off force F₁ that is ultimately required to subsequently lift wafer 18 from pad 12 and platen 14. The carbon dioxide gas formed between wafer 18 and platen 14 reduces the force on wafer 18 by reducing the atmospheric effect due to partial vacuum that is created during lift-off. Thus, ultimately lift-off force F₁ required is less than F₀ (FIG. 1) (i.e., without using carbonated water 25) so that wafer 18 breakage is less likely to occur. A removal mechanism 40 in communication with wafer 18 is used to remove wafer 18 from platen 14 by exerting requisite force to wafer 18. The removal mechanism 40 may, for example, include a motor or other suitable means now known or later developed to provide adequate force to removed wafer 18 from platen 14.

The foregoing description of the preferred embodiments of this invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

What is claimed is:

1. A method of reducing wafer removing force on a chemical mechanical planarization (CMP) tool, comprising the steps of:
planarizing a wafer on a platen at a wafer/platen interface;
applying carbonated water to the wafer/platen interface to reduce the removing force; and
removing the wafer from the platen.

2. The method of claim 1, wherein the carbonated water is deionized water.

3. The method of claim 1, wherein the carbonated water is pressurized.

4. The method of claim 1, wherein a temperature of the carbonated water is less than ambient temperature.

5. The method of claim 4, wherein the temperature of the carbonated water is between approximately 40 and 50 degrees Fahrenheit.

6. The method of claim 1, where the removing step includes lifting the wafer off the platen.

7. The method of claim 1, further comprising increasing a temperature of the carbonated water.

8. The method of claim 1, wherein the applying step follows the planarizing step.

9. The method of claim 1, wherein the platen further comprises a pad.

10. A system for reducing wafer removing force on a chemical mechanical planarization (CMP) tool, comprising:
means for planarizing a wafer on a platen at a wafer/platen interface;
means for applying carbonated water to the wafer/platen interface; and
means for removing wafer from platen.

11. The system of claim 10, wherein the carbonated water is deionized water.

12. The system of claim 10, wherein the carbonated water is pressurized.

13. The system of claim 10, wherein a temperature of the carbonated water is less than ambient temperature.

14. The system of claim 13, wherein the temperature of the carbonated water is between approximately 40 and 50 degrees Fahrenheit.

15. The system of claim 10, wherein the removing means includes means for lifting the wafer off the platen.

16. The system of claim 10, further comprising:
means for increasing temperature of the carbonated water.

17. The system of claim 10, wherein the applying means applies after the planarizing means planarizes.

18. The system of claim 10, wherein the platen further comprises a pad.

19. A method of reducing wafer removing force on a chemical mechanical planarization (CMP) tool, comprising the steps of:
planarizing a wafer on a platen at a wafer/platen interface;
applying pressurized carbonated deionized water that is between approximately 40 and 50 degrees Fahrenheit to the wafer/platen interface, to reduce wafer removing force; and
removing the wafer from the platen.

20. The method of claim 19, wherein the removing step includes lifting the wafer off the platen.
